(19) United States
(12) Patent Application Publication
(10) Pub. No.: US 2026/0129790 A1
(43) Pub. Date: May 7, 2026

(54) PIEZOELECTRIC HEAT DISSIPATION DEVICE AND HEAT DISSIPATION SYSTEM

(71) Applicant: AUDIOWELL ELECTRONICS (GUANGDONG) CO., LTD., Guangzhou (CN)

(72) Inventors: Shuguang ZHANG, Guangzhou (CN); Yan QIU, Guangzhou (CN); Chaoqun KE, Guangzhou (CN)

(73) Assignee: AUDIOWELL ELECTRONICS (GUANGDONG) CO., LTD., Guangzhou (CN)

(21) Appl. No.: 19/373,339

(22) Filed: Oct. 29, 2025

(30) Foreign Application Priority Data
Sep. 29, 2025 (CN) 202511412904.X
Nov. 1, 2024 (CN) 202411551427.0
Mar. 13, 2025 (CN) 202510298856.X

(51) Int. Cl. H05K 7/20

(52) U.S. Cl. CPC H05K 7/20172; H05K 7/20145

(57) ABSTRACT

A piezoelectric heat dissipation device and a heat dissipation system are disclosed. The piezoelectric heat dissipation device includes a housing, a connection assembly, and a piezoelectric assembly. The piezoelectric heat dissipation device and the heat dissipation system of the present disclosure have a simple structure and are easy to miniaturize. The structural arrangement of the heat dissipation system helps improve the heat dissipation effect of the piezoelectric heat dissipation device. In addition, the piezoelectric heat dissipation device and the heat dissipation system of the present disclosure have a reasonable structural design, high heat dissipation efficiency, and low energy loss, and are suitable for heat dissipation of thin electronic products. Moreover, the piezoelectric heat dissipation device and the heat dissipation system of the present disclosure can prevent the formation of fatigue cracks in piezoelectric elements due to long-term use, thereby significantly extending the service life of the product.

(To be published with FIG. 1)

### CROSS-REFERENCE TO RELATED APPLICATIONS

This application is based on and claims the benefit of priority from Chinese Patent Application No. 202510298856X filed on 13 March 2025, Chinese Patent Application No. 2024115514270 filed on 01 November 2024, and Chinese Patent Application No. 202511412904X filed on 29 September 2025. All these applications are incorporated by reference herein it their entireties.

### TECHNICAL FIELD

The present disclosure relates to the technical field of piezoelectric devices, and in particular, to a piezoelectric heat dissipation device and a heat dissipation system.

### BACKGROUND

As the running speed and computing power of electronic devices and integrated circuit chips continue to increase, heat generation is also increasing dramatically. To address the heat generated by the electronic devices, various heat dissipation mechanisms such as mechanical fans have been proposed. However, with the continuous trend toward miniaturization of electronic devices, conventional heat dissipation schemes using mechanical fans are no longer applicable.

In recent years, piezoelectric cooling fans have gradually attracted attention as a novel heat dissipation technology. Piezoelectric cooling fans utilize the bending vibrations of piezoelectric materials to drive a fluid to flow, thereby achieving heat dissipation.

However, piezoelectric cooling fans also face a series of challenges, such as the growing demand for heat dissipation and the need for product miniaturization and thinning.

Moreover, existing piezoelectric fans still have room for improvement in the aspects such as structural design, heat dissipation efficiency, and reliability, and need to be further improved.

In addition, existing piezoelectric cooling fan technologies also have some drawbacks. For example, over long-term operation, the piezoelectric material in piezoelectric cooling fans undergoes significant bending deformation, which can easily cause fatigue cracks, leading to product failure and shortening the service life of the product.

### SUMMARY

The present disclosure aims to at least solve one of the technical problems in the related art.

A first aspect of the present disclosure is to design a piezoelectric heat dissipation device and a heat dissipation system to achieve miniaturization and thinning.

To achieve the above objective, the present disclosure provides a piezoelectric heat dissipation device, including: a housing, a second connection assembly, and a piezoelectric assembly, where:

the piezoelectric assembly is arranged in the housing and is connected to the housing through the second connection assembly, the piezoelectric assembly includes a first piezoelectric element, a diaphragm, a support frame, and a jet plate connected in sequence along a first direction, the jet plate is provided with jet holes, and an energy conversion cavity in communication with the jet holes is defined by the diaphragm, the support frame, and the jet plate; and

the housing includes a housing body and an air exit plate, the housing body is provided with a first opening facing the jet plate in the first direction, the air exit plate is arranged to cover the first opening, the air exit plate is provided with air exit holes in communication with the jet holes, and the housing body is further provided with an air inlet in communication with the jet holes.

Compared with the existing technology, the piezoelectric heat dissipation device and the heat dissipation system according to the embodiments of the first aspect of the present disclosure have the following advantages.

The piezoelectric heat dissipation device and the heat dissipation system according to the embodiments of the present disclosure have a simple structure. The piezoelectric assembly serves as a basic driving unit, and includes the first piezoelectric element, the diaphragm, the support frame, and the jet plate. The piezoelectric heat dissipation device and the heat dissipation system do not have the movable blade structure of a conventional fan, and therefore are easy to miniaturize and can be used in a thinner electronic product. In addition, in the present disclosure, the jet holes are in communication with the air exit holes, and the air inlet is in communication with the air exit holes, thus forming good air inlet and air outlet paths, to ensure the heat dissipation effect of the heat dissipation device and improve the heat dissipation efficiency.

### BRIEF DESCRIPTION OF DRAWINGS

FIG. 1 is a schematic structural sectional view of a piezoelectric heat dissipation device according to a first embodiment of a first aspect of the present disclosure;

FIG. 2 is a schematic structural sectional view of the piezoelectric heat dissipation device according to the first embodiment of the first aspect of the present disclosure, in which a diaphragm is deformed downward;

FIG. 3 is a schematic structural sectional view of the piezoelectric heat dissipation device according to the first embodiment of the first aspect of the present disclosure, in which a diaphragm is deformed upward;

FIG. 4 is a schematic exploded view of a piezoelectric heat dissipation device according to a first embodiment of a first aspect of the present disclosure;

FIG. 5 is a schematic structural sectional view of a piezoelectric heat dissipation device according to a second embodiment of the first aspect of the present disclosure;

FIG. 6 is a schematic structural sectional view of a piezoelectric heat dissipation device according to a third embodiment of the first aspect of the present disclosure;

FIG. 7 is a schematic structural sectional view of a piezoelectric heat dissipation device according to a fourth embodiment of the first aspect of the present disclosure;

FIG. 8 is a schematic structural top view of an interior of the piezoelectric heat dissipation device according to the fourth embodiment of the first aspect of the present disclosure;

FIG. 9 is a schematic structural sectional view of a piezoelectric heat dissipation device according to a fifth embodiment of the first aspect of the present disclosure;

FIG. 10 is a three-dimensional schematic structural diagram of the piezoelectric heat dissipation device according to the fifth embodiment of the first aspect of the present disclosure;

FIG. 11 is a three-dimensional schematic structural diagram of a piezoelectric heat dissipation device according to a sixth embodiment of the first aspect of the present disclosure;

FIG. 12 is a schematic structural top view of the piezoelectric heat dissipation device according to the sixth embodiment of the first aspect of the present disclosure;

FIG. 13 is a schematic structural top view of a piezoelectric heat dissipation device according to a seventh embodiment of the first aspect of the present disclosure;

FIG. 14 is a schematic structural sectional view of a heat dissipation system according to the first embodiment of the first aspect of the present disclosure;

FIG. 15 is a three-dimensional schematic structural diagram of the heat dissipation system according to the first embodiment of the first aspect of the present disclosure;

FIG. 16 is a schematic structural sectional view of a heat dissipation system according to the second embodiment of the first aspect of the present disclosure;

FIG. 17 is a schematic structural sectional view of a heat dissipation system according to the third embodiment of the first aspect of the present disclosure;

FIG. 18 is a schematic structural sectional view of a heat dissipation system according to the fourth embodiment of the first aspect of the present disclosure;

FIG. 19 is a schematic structural sectional view of a piezoelectric heat dissipation device according to a first embodiment of a second aspect of the present disclosure;

FIG. 20 is a schematic structural sectional view of the piezoelectric heat dissipation device according to the first embodiment of the second aspect of the present disclosure, in which a diaphragm is deformed downward;

FIG. 21 is a schematic structural sectional view of the piezoelectric heat dissipation device according to the first embodiment of the second aspect of the present disclosure, in which a diaphragm is deformed upward;

FIG. 22 is a schematic structural sectional view of a piezoelectric heat dissipation device according to a second embodiment of the second aspect of the present disclosure;

FIG. 23 is a schematic structural sectional view of the piezoelectric heat dissipation device according to the second embodiment of the second aspect of the present disclosure, in which a diaphragm is deformed downward;

FIG. 24 is a schematic structural sectional view of the piezoelectric heat dissipation device according to the second embodiment of the second aspect of the present disclosure, in which a diaphragm is deformed upward;

FIG. 25 is a schematic structural sectional view of a piezoelectric heat dissipation device according to a third embodiment of the second aspect of the present disclosure;

FIG. 26 is a schematic structural sectional view of the piezoelectric heat dissipation device according to the third embodiment of the second aspect of the present disclosure, in which a diaphragm is deformed downward;

FIG. 27 is a schematic structural sectional view of the piezoelectric heat dissipation device according to the third embodiment of the second aspect of the present disclosure, in which a diaphragm is deformed upward;

FIG. 28 is a schematic diagram showing mounting of an elastic assembly in the piezoelectric heat dissipation device according to the third embodiment of the second aspect of the present disclosure;

FIG. 29 is a schematic structural sectional view of a piezoelectric heat dissipation device according to a fourth embodiment of the second aspect of the present disclosure;

FIG. 30 is a schematic structural sectional view of the piezoelectric heat dissipation device according to the fourth embodiment of the second aspect of the present disclosure, in which a diaphragm is deformed downward;

FIG. 31 is a schematic structural sectional view of the piezoelectric heat dissipation device according to the fourth embodiment of the second aspect of the present disclosure, in which a diaphragm is deformed upward;

FIG. 32 is a schematic diagram showing mounting of an elastic assembly in a piezoelectric heat dissipation device according to a fifth embodiment of the second aspect of the present disclosure;

FIG. 33 is a schematic structural sectional view of a piezoelectric heat dissipation device according to a sixth embodiment of the second aspect of the present disclosure;

FIG. 34 is a schematic structural sectional view of the piezoelectric heat dissipation device according to the sixth embodiment of the second aspect of the present disclosure, in which a diaphragm is deformed downward;

FIG. 35 is a schematic structural sectional view of the piezoelectric heat dissipation device according to the sixth embodiment of the second aspect of the present disclosure, in which a diaphragm is deformed upward;

FIG. 36 is a schematic structural sectional view of a piezoelectric heat dissipation device according to a seventh embodiment of the second aspect of the present disclosure;

FIG. 37 is a schematic structural sectional view of the piezoelectric heat dissipation device according to the seventh embodiment of the second aspect of the present disclosure, in which a diaphragm is deformed downward;

FIG. 38 is a schematic structural sectional view of the piezoelectric heat dissipation device according to the seventh embodiment of the second aspect of the present disclosure, in which a diaphragm is deformed upward;

FIG. 39 is a schematic structural diagram of a heat dissipation system according to an eighth embodiment of the second aspect of the present disclosure;

FIG. 40 is a sectional view of the heat dissipation system according to the eighth embodiment of the second aspect of the present disclosure;

FIG. 41 is a schematic structural diagram of a piezoelectric heat dissipation device according to an embodiment of a third aspect of the present disclosure;

FIG. 42 is a diagram showing projections of a piezoelectric element and a diaphragm in a first direction in a piezoelectric heat dissipation device according to an embodiment of the third aspect of the present disclosure;

FIG. 43 is a schematic exploded view of a piezoelectric heat dissipation device according to a first embodiment of the third aspect of the present disclosure;

FIG. 44 is a schematic structural diagram of the piezoelectric heat dissipation device according to the first embodiment of the third aspect of the present disclosure;

FIG. 45 is a schematic structural diagram of the piezoelectric heat dissipation device according to the first embodiment of the third aspect of the present disclosure;

FIG. 46 is a schematic structural diagram of the piezoelectric heat dissipation device according to the first embodiment of the third aspect of the present disclosure;

FIG. 47 is a schematic structural diagram of a piezoelectric heat dissipation device according to a second embodiment of the third aspect of the present disclosure;

FIG. 48 is a schematic structural diagram of the piezoelectric heat dissipation device according to the second embodiment of the third aspect of the present disclosure;

FIG. 49 is a schematic structural diagram of the piezoelectric heat dissipation device according to the second embodiment of the third aspect of the present disclosure;

FIG. 50 is a schematic structural diagram one of a piezoelectric heat dissipation device according to a third embodiment of the third aspect of the present disclosure;

FIG. 51 is a schematic structural diagram two of the piezoelectric heat dissipation device according to the third embodiment of the third aspect of the present disclosure; and

FIG. 52 is a schematic structural diagram three of the piezoelectric heat dissipation device according to the third embodiment of the third aspect of the present disclosure.

Reference numerals: piezoelectric element 100; central hole 110; diaphragm 120; support frame 130; energy conversion cavity 140; jet plate 150; jet hole 160; air exit plate 170; air exit hole 180; first connection assembly 190; intake passage 200; housing 210; window 220; air inlet 230; housing body 240; first opening 250; second connection assembly 260; elastic supporting member 270; first piezoelectric element 280; second piezoelectric element 290; heat generating element 300; heat-conducting plate 310; hot end 320; cold end 330; piezoelectric assembly 340; energy conversion cavity 350; supporting member 360; first side surface 370; second side surface 380; curved structure 390; annular structure 400; second opening 420; elastic assembly 430; elastic cantilever 440; baffle plate 450; outlet passage 460; air outlet 470; first direction x; second direction y.

### DETAILED DESCRIPTION

The present disclosure is described in further detail in conjunction with accompanying drawings and embodiments. It is to be understood that the embodiments described herein are merely used for illustrating the present disclosure, and are not intended to limit the present disclosure.

In the description of the present disclosure, it should be understood that, terms such as “upper,” “lower,” “front,” “rear,” “left,” “right,” “vertical,” “horizontal,” “top,” “bottom,” “inner,” “outer,” and the like are based on orientation or positional relationships shown in the accompanying drawings, and are used only for ease and brevity of illustration and description, rather than indicating or implying that the mentioned apparatus or element must have a particular orientation or must be constructed and operated in a particular orientation. Therefore, such terms should not be construed as limiting of the present disclosure.

In the present disclosure, unless specified or limited otherwise, the terms “connected,” “coupled,” “fixed” and the like are used broadly, and may be, for example, fixed connections, detachable connections, or integral connections; may also be mechanical connections, or welded connections; may also be direct connections, or indirect connections via intervening structures; may also be inner communications or interaction of two elements. The specific meaning of the above terms within the present disclosure may be understood by those having ordinary skills in the art according to particular circumstances.

In present disclosure, terms such as “first” and “second” are used to describe various types of information; however, such information should not be limited to these terms, which are merely used to distinguish information of the same type from one another. For example, without departing from the scope of the present disclosure, “first” information may also be referred to as “second” information, and similarly, “second” information may also be referred to as “first” information.

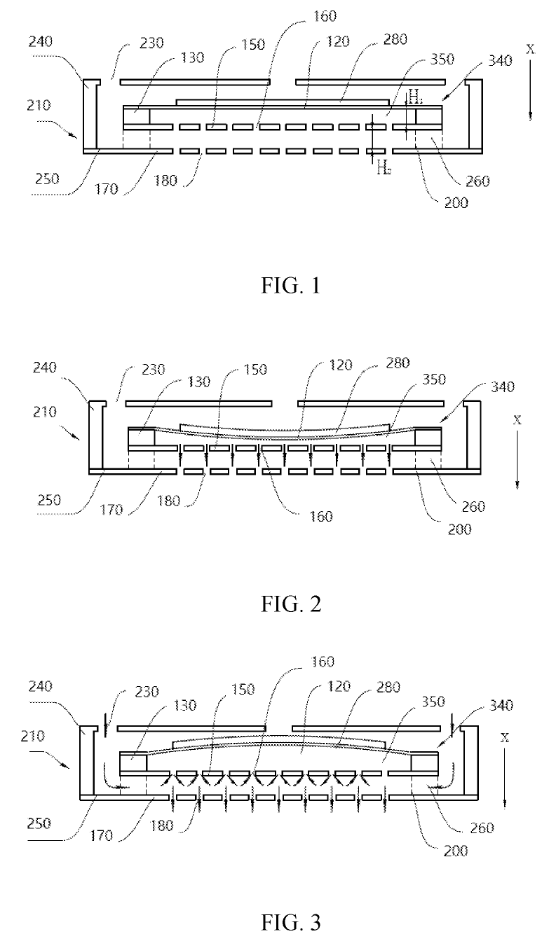

Referring to FIG. 1 to FIG. 18, the present disclosure proposes improvements in a first aspect to cope with a series of challenges, such as the growing demand for heat dissipation and the need for product miniaturization and thinning.

Referring to FIG. 1, an embodiment of the present disclosure provides a piezoelectric heat dissipation device, which includes a housing 210, a second connection assembly 260, and a piezoelectric assembly 340.

The piezoelectric assembly 340 is arranged in the housing 210 and is connected to the housing 210 through the second connection assembly 260. The piezoelectric assembly 340 includes a first piezoelectric element 280, a diaphragm 120, a support frame 130, and a jet plate 150 connected in sequence along the first direction x. The jet plate 150 is provided with jet holes 160. An energy conversion cavity 350 in communication with the jet holes 160 is defined by the diaphragm 120, the support frame 130, and the jet plate 150. The housing 210 includes a housing body 240 and an air exit plate 170. The housing body 240 is provided with a first opening 250 facing the jet plate 150 in the first direction x. The air exit plate 170 is arranged to cover the first opening 250. The air exit plate 170 is provided with air exit holes 180 in communication with the jet holes 160. The housing body 240 is further provided with an air inlet 230 in communication with the jet holes 160.

There may be one or more air inlets 230 provided on the housing body 240. The air inlet(s) 230 may be provided in a middle, periphery, or side wall of the housing body 240. The air inlet(s) 230 may be rectangular, circular, tapered, or in other shapes. The diaphragm 120 may be a metal film made of stainless steel, copper, aluminum alloy, titanium alloy, etc., or may be a non-metal film made of polyimide, polyethylene terephthalate (PET), epoxy resin, rubber, etc., and may have a thickness ranging from 0.01 mm to 1 mm. The first piezoelectric element 280 is fixed to the diaphragm 120. The first piezoelectric element 280 may be an independent piezoelectric crystal, which, together with the diaphragm 120, constitutes a transducer capable of generating a bending vibration; may be a piezoelectric unimorph consisting of a piezoelectric crystal and an elastic substrate; may be a piezoelectric bimorph formed by attaching piezoelectric crystals to two surfaces of an elastic substrate; or may be a piezoelectric laminate formed by bonding of two piezoelectric crystals and capable of generating a bending vibration. All the above schemes share the common feature of being capable of driving the diaphragm 120 to generate a bending deformation vibration. The piezoelectric crystal may be a multilayer piezoelectric ceramic or a single-layer piezoelectric ceramic. The first piezoelectric element 280 may be of any structural shape, e.g., circular, square, annular, etc.

A dimension from the diaphragm 120 to the jet plate 150 in the first direction x is a height H₁ of the energy conversion cavity 350. To prevent the jet plate 150 from interfering with the vibration of the diaphragm 120, H₁ needs to be greater than a maximum downward amplitude of the diaphragm 120. The closer the jet plate 150 is to the diaphragm 120, the higher the energy obtained by the air, and the larger the initial velocity of the air. In some embodiments, H₁ ranges from 20 μm to 500 μm. In some embodiments, H₁ ranges from 20 μm to 300 μm. In some embodiments, H₁ ranges from 50 μm to 500 um.

The jet holes 160 are evenly distributed on the jet plate 150. The jet holes 160 are generally circular, or may be rectangular, waist-shaped, elliptical, or in other shapes. A diameter of a single jet hole 160 may be 5 μm to 500 um. The number of the jet holes 160 is determined by the total area of the jet plate 150 and the area of a single jet hole 160. The total area of the jet holes 160 accounts for 0.1% to 10% of the total area of the jet plate 150. In some embodiments, the number of the jet holes 160 is 10 to 2000.

The air exit holes 180 on the air exit plate 170 are configured to allow air to be jetted through the jet holes 160. Generally, the air exit holes 180 may or may not correspond one-to-one to the jet holes 160. For example, a plurality of air exit holes 180 may be combined into one air exit hole 180 for air from a plurality of jet holes 160 to pass through. Generally, the size of the air exit hole 180 is larger than the size of the jet hole 160, or may be equal to or smaller than the size of the jet hole 160, which may be adjusted according to a required flow rate and noise level. In some embodiments, the total area of the air exit holes 180 accounts for 1% to 20% of the total area of the air exit plate 170.

A distance between the jet plate 150 and the air exit plate 170 is defined as H₂, which affects the magnitude of the flow rate of air entering the energy conversion cavity 350 from the air inlet 230, and also affects the magnitude of the flow rate of air carried away during entrainment of air jets from the jet holes 160. The value of H₂ may be adjusted according to a required flow rate and noise level. In some embodiments, H₂ ranges from 0.1 mm to 2 mm. In some embodiments, H₂ ranges from 0.1 mm to 1 mm. In some embodiments, H₂ ranges from 0.5 mm to 2 mm.

An alternating current (AC) excitation signal is applied to the piezoelectric element to cause the diaphragm 120 to vibrate at high frequency, thereby performing work on air and driving the air to flow directionally. The frequency of the applied excitation signal is in an ultrasonic frequency range, so that generation of noise audible to human ears can be avoided. When the frequency of the excitation signal is the same as or close to the characteristic frequency of the piezoelectric element, a maximum flow rate can be obtained. The Helmholtz resonance frequency of the energy conversion cavity 350 may be designed to be close to the frequency of a drive signal to maximize the utilization of system energy. The Helmholtz resonance frequency of the energy conversion cavity 350 may also have other values.

In some improved schemes of the first aspect of the present disclosure, one side of the second connection assembly 260 is connected to an edge of the jet plate 150, another side of the second connection assembly 260 is connected to the air exit plate 170, the second connection assembly 260 is provided with an intake passage 200, and the air inlet 230 is in communication with the jet holes 160 through the intake passage 200.

As shown in FIG. 1, in some improved schemes of the first aspect of the present disclosure, one side of the second connection assembly 260 is connected to an edge of the jet plate 150, another side of the second connection assembly 260 is connected to the air exit plate 170, the second connection assembly 260 is provided with an intake passage 200, and the air inlet 230 is in communication with the jet holes 160 through the intake passage 200. The piezoelectric assembly 340 is connected to the air exit plate 170 through the second connection assembly 260 and is thus supported.

The first piezoelectric element 280 vibrates at a high speed under an AC drive signal of a particular frequency, and causes the diaphragm 120 to periodically undergo upward and downward bending deformations. As shown in FIG. 2, the first piezoelectric element 280 is deformed downward, air in the energy conversion cavity 350 is compressed to achieve a forward initial velocity, and the air flows outward through the jet holes 160 on the jet plate 150 to create air jets, which form a vortex pair and entrain air nearby. The air ejected from the jet holes 160 forms air jets, which entrain air nearby, continue to flow forward, and are then ejected through the air exit holes 180.

As shown in FIG. 3, the first piezoelectric element 280 is deformed upward, the pressure in the energy conversion cavity 350 decreases, and outside air enters the energy conversion cavity 350 from the air inlet 230 through the jet holes 160. Due to inertia, the air previously ejected from the energy conversion cavity 350 has passed through the air exit holes 180 and is far away from the jet holes 160. In this case, due to the blocking effect of the air exit plate 170, only a small amount of air flows back, and the rest of the air enters the energy conversion cavity 350 mainly from the air inlet 230 through the intake passage 200 of the second connection assembly 260. By continuously repeating the processes shown in FIG. 2 and FIG. 3, cooling air can be continuously sucked in from the air inlet 230 and finally be ejected from the air exit holes 180.

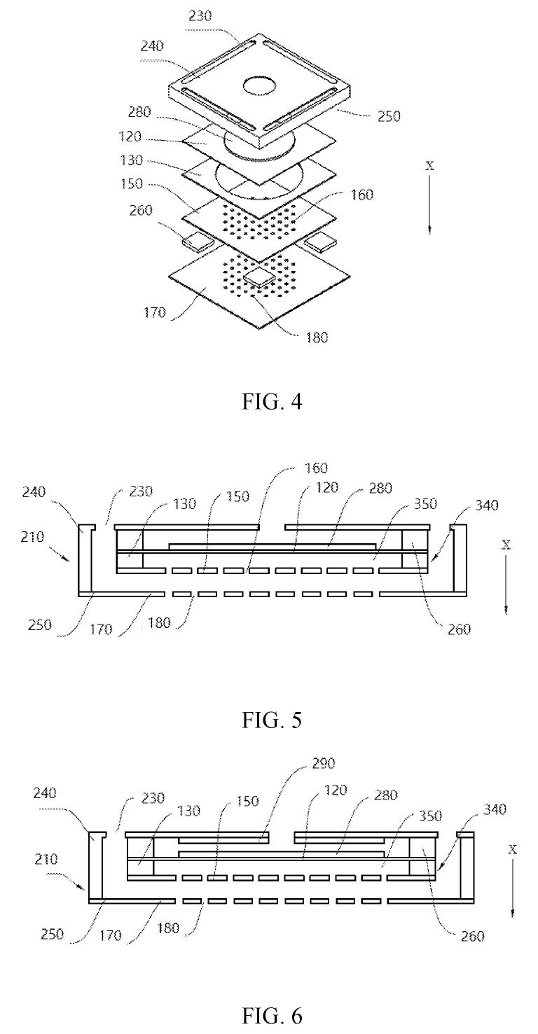

FIG. 4 is a three-dimensional diagram of a specific implementation scheme of a first embodiment of the present disclosure. As shown in FIG. 4, the piezoelectric heat dissipation device includes, from top to bottom, a housing body 240, a first piezoelectric element 280, a diaphragm 120, a support frame 130, a jet plate 150, a second connection assembly 260, and an air exit plate 170, which are fixed by welding or an adhesive.

The housing body 240 is made of a metal or plastic material and is provided with an air inlet 230.

The diaphragm 120 is a rectangular film, as shown in the figure. However, the diaphragm 120 may also be circular or in other shapes. A middle portion of the diaphragm 120 is fixed to the first piezoelectric element 280 by adhesion. An AC drive signal is applied to the first piezoelectric element 280 to cause the first piezoelectric element 280 to generate a bending vibration, thereby driving the diaphragm 120 to vibrate together. A periphery of the diaphragm 120 and a periphery of the jet plate 150 are both fixed to the support frame 130, and a clearance region is provided in a middle of the support frame 130 to form an energy conversion cavity 350.

The jet plate 150 is provided with a plurality of jet holes 160 evenly distributed in a hollow region of the energy conversion cavity 350.

Another side of the jet plate 150 is fixed to the second connection assembly 260, and an intake passage 200 for intake of air is provided around the second connection assembly 260. The air exit plate 170 is located on another side of the second connection assembly 260, and the piezoelectric assembly 340 is fixed to the air exit plate 170 through the second connection assembly 260.

This figure merely shows one embodiment of the present disclosure, and other specific implementations are possible.

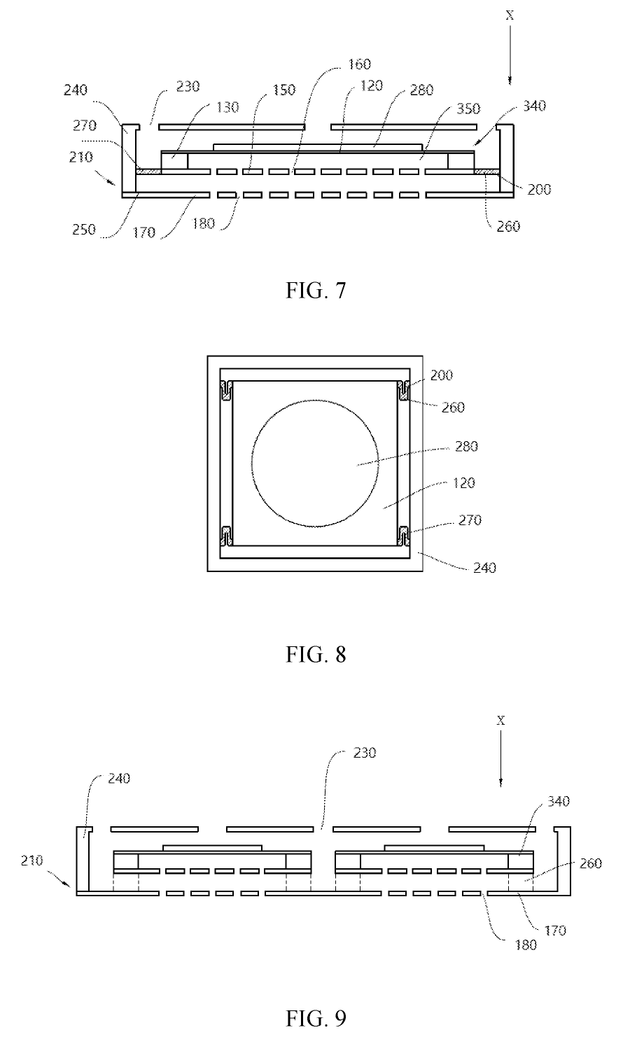

As shown in FIG. 7, in some improved schemes of the first aspect of the present disclosure, one side of the second connection assembly 260 is connected to an outer peripheral wall of the piezoelectric assembly 340 in the first direction x, another side of the second connection assembly 260 is connected to an inner peripheral wall of the housing body 240 in the first direction x, the second connection assembly 260 is provided with an intake passage 200, and the air inlet 230 is in communication with the jet holes 160 through the intake passage 200.

In this embodiment, the basic structure of the piezoelectric assembly 340 is the same as that in the above embodiments, the piezoelectric heat dissipation device includes the housing 210, the first piezoelectric element 280, the diaphragm 120, the support frame 130, the jet plate 150, and the air exit plate 170, and the piezoelectric assembly 340 is connected and fixed to a side wall of the housing body 240 through the second connection assembly 260.

As shown in FIG. 5, in some improved schemes of the first aspect of the present disclosure, one side of the second connection assembly 260 is connected to an edge of the diaphragm 120, and another side of the second connection assembly 260 is connected to an inner wall of the housing body 240 facing the diaphragm 120 in the first direction x. In other words, in the second embodiment, the piezoelectric assembly 340 is fixed to a top of the housing body 240 through the second connection assembly 260 to form a suspended structure. As such, when cooling air flows from the air inlet 230 through a region between the jet plate 150 and the air exit plate 170, the cooling air does not need to pass through the second connection assembly 260, i.e., the intake passage 200 is larger than the intake passage 200 in other embodiments, thereby achieving a higher air flow rate.

In addition, in the second embodiment, the top of the housing body 240, the second connection assembly 260, and the diaphragm 120 form a resonant cavity. The Helmholtz resonance frequency of the resonant cavity may be designed to be the same as or close to the frequency of a drive signal, so that the diaphragm 120 and the resonant cavity can resonate, the amplitude can be increased, and the flow rate of the heat dissipation device can be increased.

In some improved schemes of the first aspect of the present disclosure, the piezoelectric heat dissipation device further includes a second piezoelectric element 290, the second piezoelectric element 290 is arranged on an inner wall of the housing body 240 facing the diaphragm 120 in the first direction x, and a movement direction of the second piezoelectric element 290 is opposite to that of the first piezoelectric element 280. This embodiment is an improvement of the second embodiment. The second piezoelectric element 290 is fixed to a top of the housing body 240. When a drive signal is applied to the second piezoelectric element 290, the second piezoelectric element 290 can drive the top of the housing body 240 to generate a bending vibration similar to that of the diaphragm 120. Drive signals of the same frequency are applied to the second piezoelectric element 290 and the diaphragm 120 to cause the second piezoelectric element 290 and the diaphragm 120 to vibrate in opposite directions. The second piezoelectric element 290 and the diaphragm 120 resonate, and forces applied by the second piezoelectric element 290 and the diaphragm 120 to the second connection assembly 260 during vibration cancel each other out, so that the amplitude of the diaphragm 120 can be increased, thereby increasing the flow rate of the heat dissipation device.

In some improved schemes of the first aspect of the present disclosure, the second connection assembly 260 includes at least two elastic supporting members 270, the at least two elastic supporting members 270 are connected to the piezoelectric assembly 340 and the housing 210, and the at least two elastic supporting members 270 are arranged at intervals along a circumferential direction of the piezoelectric assembly 340. The piezoelectric assembly 340 is fixedly connected to the housing 210 through a plurality of elastic supporting members 270. During operation of the piezoelectric heat dissipation device, the vibration of the first piezoelectric element 280 is transmitted to the air exit plate 170 and the housing body 240 through the second connection assembly 260 to drive the entire housing 210 to vibrate. As a result, part of the energy is lost and the efficiency is reduced. In this embodiment, the piezoelectric assembly 340 is fixedly connected through the elastic supporting members 270, which can provide a damping effect during operation of the heat dissipation device, so that the vibration transmitted to the housing 210 during operation of the piezoelectric assembly 340 can be minimized, thereby effectively reducing energy loss and improving the heat dissipation efficiency. Especially when the piezoelectric assembly 340 is connected to an inner peripheral wall of the housing body 240 through the second connection assembly 260, a more significant damping effect is achieved.

As shown in FIG. 8, the elastic supporting members 270 may be U-shaped leaf springs. Elastic supporting members 270 of other structures are also applicable to this scheme, as long as the effect of reducing the vibration of the external structure of the heat dissipation device and improving the heat dissipation efficiency can be realized.

In some improved schemes of the first aspect of the present disclosure, the piezoelectric heat dissipation device includes a plurality of piezoelectric assemblies 340, and the piezoelectric assemblies 340 are arranged at intervals in a direction perpendicular to the first direction x.

As shown in FIG. 9, a housing 210 of a piezoelectric heat dissipation device according to a fifth embodiment of the present disclosure includes a housing body 240 and an air exit plate 170, and a plurality of piezoelectric assemblies 340 are provided in the housing body 240. Each piezoelectric assembly 340 has the same structure as the piezoelectric assembly 340 in the first embodiment, and includes a first piezoelectric element 280, a diaphragm 120, a support frame 130, and a jet plate 150.

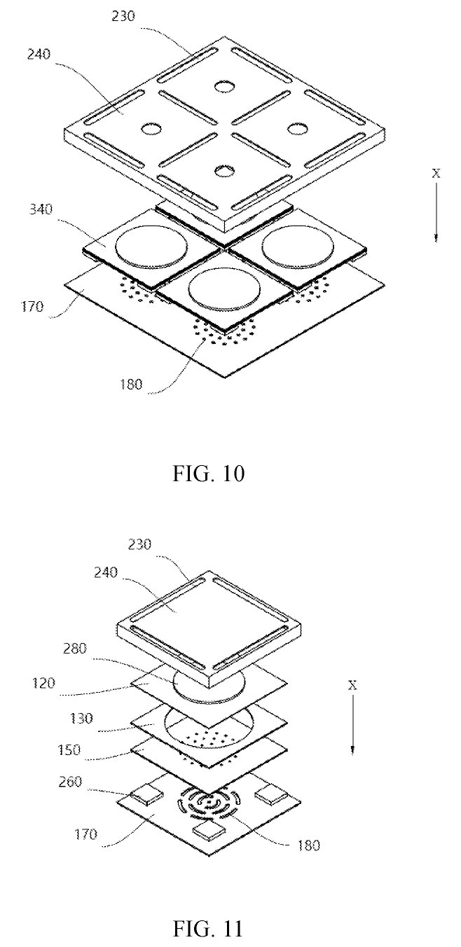

FIG. 10 is a three-dimensional diagram of the fifth embodiment, showing that four piezoelectric assemblies 340 are arranged in the housing body 240. In this embodiment, more energy conversion structures can be integrated in a limited cavity, so a higher flow rate than that in the first embodiment can be achieved. In addition, the area of the air exit hole 180 in this embodiment is increased, and the heat dissipation area is increased, which is suitable for occasions requiring a high flow rate and a large heat dissipation area.

In some other specific embodiments, the number of piezoelectric assemblies 340 arranged in the housing 210 of one piezoelectric heat dissipation device may have other values, e.g., 2, 8, etc.

In some improved schemes of the first aspect of the present disclosure, the jet plate 150 is provided with a plurality of jet holes 160, the air exit plate 170 is provided with a plurality of air exit holes 180, and in the first direction x, one air exit hole 180 is arranged corresponding to a plurality of jet holes 160.

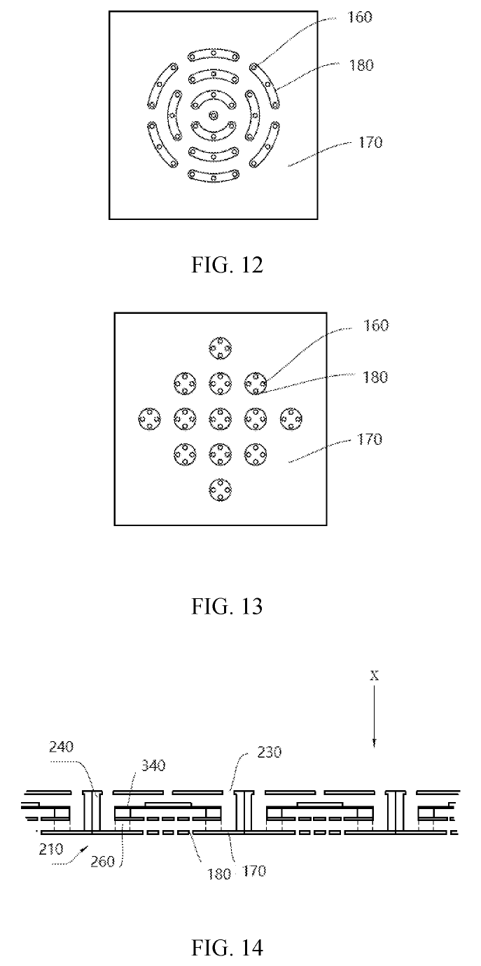

As shown in FIG. 11, in a sixth embodiment, the air exit holes 180 on the air exit plate 170 are not circular and do not correspond one-to-one to the jet holes 160 on the jet plate 150, but are arc-shaped elongated holes. As shown in FIG. 12, each elongated air exit hole 180 may correspond to three jet holes 160, allowing air ejected from the three jet holes 160 to pass through. In the first embodiment, when air ejected from the jet holes 160 passes through the small air exit holes 180, the velocity and pressure of the air are changed drastically, causing air nearby to vibrate and generate airflow noise. The design of this embodiment can increase the sectional area of the air exit holes 180, and reduce the rate of change of the airflow speed, thereby reducing the noise generated when the air flow passes through the air exit holes 180.

In addition to the arc-shaped elongated holes shown in FIG. 12, in a seventh embodiment shown in FIG. 13, larger circular air exit holes 180 may be used, and each air exit hole 180 can allow air ejected from four jet holes 160 to pass through. Such a configuration can also reduce the airflow noise.

The configuration of the air exit holes 180 is not limited to the above two methods, other methods that can achieve similar effects are also feasible, and corresponding schemes may be selected according to actual requirements.

As an expanded scheme, a heat dissipation system according to an embodiment of the present disclosure includes one or more piezoelectric heat dissipation devices described above. The piezoelectric heat dissipation devices are arranged at intervals in a direction perpendicular to the first direction x. Outer peripheral walls of neighboring housing bodies 240 are connected to each other. The air inlet 230 is provided on a side of the housing body 240 facing away from the first opening 250 in the first direction x.

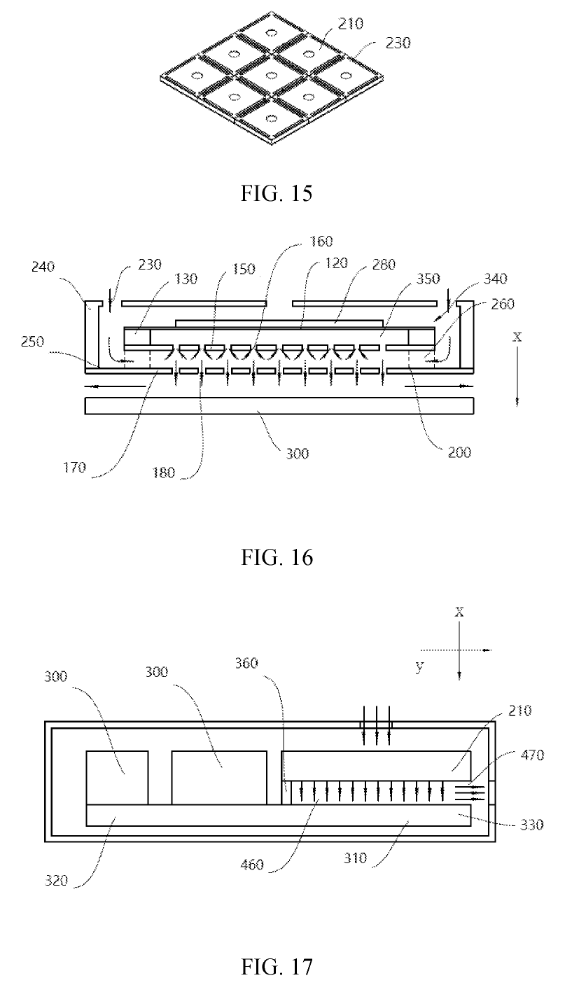

FIG. 14 and FIG. 15 depict a heat dissipation system including a plurality of piezoelectric heat dissipation devices.

As shown in FIG. 14, each piezoelectric heat dissipation device has the same structure as the piezoelectric heat dissipation device in the first embodiment. Because the flow rate and the heat dissipation area of the entire heat dissipation system is the sum of the flow rates and the heat dissipation areas of the piezoelectric heat dissipation devices, the theoretical flow rate and heat dissipation area of the heat dissipation system may be designed according to actual requirements. Therefore, the heat dissipation system is suitable for occasions requiring a high flow rate and a large heat dissipation area that cannot be satisfied by a single piezoelectric heat dissipation device. In addition, the heat dissipation system is easy to deploy and easy to use.

In some improved schemes of the first aspect of the present disclosure, the heat dissipation system further includes a heat generating element 300, the air inlet 230 is provided on the side of the housing body 240 facing away from the first opening 250 in the first direction x, and the heat generating element 300 is arranged spaced apart from a side of the piezoelectric heat dissipation device facing the air exit plate 170 in the first direction x.

As shown in FIG. 16, the piezoelectric heat dissipation device may be directly fixed to a surface of the heat generating element 300, the air exit holes 180 of the piezoelectric heat dissipation device are adjacent to one side of the heat generating element 300, the air exit holes 180 are spaced apart from the surface of the heat generating element 300 by a distance, and an outlet passage 460 is reserved between the air exit holes 180 and the surface of the heat generating element 300.

The air inlet 230 of the piezoelectric heat dissipation device is arranged far away from the heat generating element 300. During operation of the piezoelectric heat dissipation device, cooling air can be continuously sucked in from the air inlet 230 and ejected to the heat generating element 300 through the air exit holes 180 for heat exchange. Then, the cooling air becomes hot, and finally is discharged from the outlet passage 460, so that a large amount of heat is taken away to realize a heat dissipation effect.

In some improved schemes of the first aspect of the present disclosure, the heat dissipation system further includes a heat generating element 300, a heat-conducting plate 310, and a supporting member 360. The heat-conducting plate 310 includes a hot end 320 and a cold end 330 opposite to the hot end 320 in a second direction y. The heat generating element 300 is pressed against the hot end 320. The piezoelectric heat dissipation device is arranged spaced apart from the cold end 330 in the first direction x. One side of the supporting member 360 is connected to the heat-conducting plate 310, and another side of the supporting member 360 is connected to an edge of the piezoelectric heat dissipation device. An outlet passage 460 is defined by the air exit plate 170, the supporting member 360, and the heat-conducting plate 310. An air outlet 470 is provided on one side of the supporting member 360 adjacent to the cold end 330 in the second direction y. The air outlet 470 is in communication with the outlet passage 460. The air inlet 230 is provided on the side of the housing body 240 facing away from the first opening 250 in the first direction x, or on a side of the housing body 240 facing away from the air outlet 470 in the second direction y. The second direction y is perpendicular to the first direction x.

As shown in FIG. 17, in the third embodiment of the present disclosure, the heat generating element 300 is connected to one end of the heat-conducting plate 310, and the piezoelectric heat dissipation device is connected to another end of the heat-conducting plate 310. In this case, the end with the heat generating element 300 has a higher temperature and is the hot end 320, and the end with the piezoelectric heat dissipation device has a lower temperature and is the cold end 330. Through heat conduction, heat of the hot end 320 continuously flows to the cold end 330. A casing is provided as an electronic product casing to cover the components of the heat dissipation system. An air inlet port and an air outlet port are provided on the casing. The piezoelectric heat dissipation device continuously sucks in cooling air through the air inlet port and the air inlet 230, ejects the air to the cold end 330 of the heat-conducting plate 310, and finally discharges the air through the air outlet port. This process takes away a large amount of heat, so the temperature of the cold end 330 of the heat conducting plate 310 is reduced. Then, the cold end 330 absorbs heat from the hot end 320, so that the temperature of the hot end 320 is reduced, and finally the temperature of the heat generating element 300 is reduced. This process is repeatedly performed to achieve a heat dissipation effect for the electronic product.

Because the heat generating element 300 and the piezoelectric heat dissipation device are fixed side by side on the heat-conducting plate 310, space in the vertical direction can be greatly saved. The piezoelectric heat dissipation device used in this embodiment has a compact structure, the size and thickness of which are much smaller than that of a conventional fan, and is similar to that of a conventional chip. Therefore, theoretically, the piezoelectric heat dissipation device can achieve a good heat dissipation effect without additionally increasing the thickness of an electronic product.

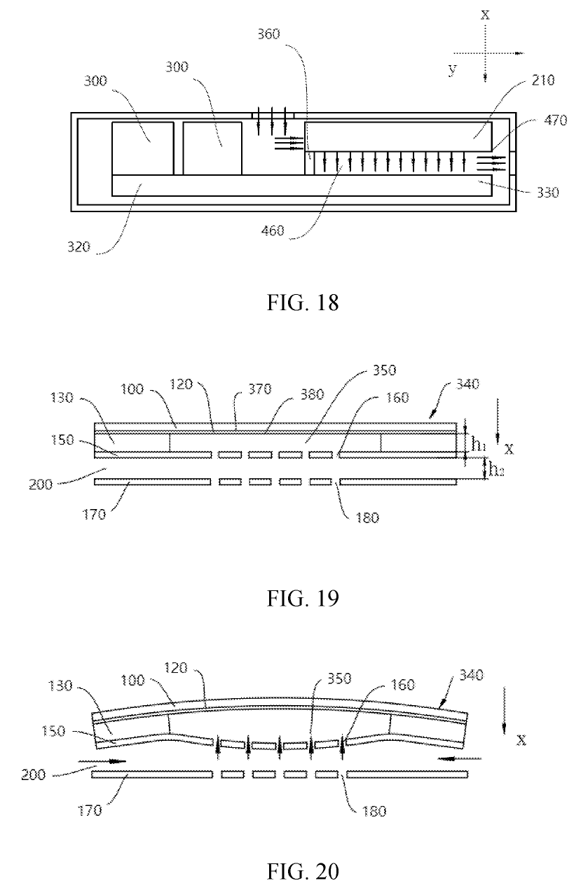

A heat dissipation method in FIG. 18 is the same as that in FIG. 17, except that the air inlet 230 of the piezoelectric heat dissipation device is provided on a side surface, and there is almost no need to reserve an airflow passage above the piezoelectric heat dissipation device. Therefore, the heat dissipation system shown in FIG. 18 can be used in a thinner electronic product.

Based on the above, the embodiments of the present disclosure provide a piezoelectric heat dissipation device and a heat dissipation system, which have the following advantages.

1. Simple structure and ease to miniaturize: The piezoelectric assembly 340 serves as a basic driving unit. The energy conversion cavity 350 is defined by the first piezoelectric element 280, the diaphragm 120, the support frame 130, and the jet plate 150 to eject air to the air exit plate 170. The piezoelectric heat dissipation device and the heat dissipation system do not have the movable blade structure of a conventional fan, and therefore are easy to miniaturize and can be used in a thinner electronic product.

2. Large distribution area of the air outlet, and good uniform heat dissipation effect: A conventional synthetic jet plate is generally provided with jet holes only in a middle portion thereof, i.e., the jet area is concentrated, the heat dissipation area is small, and the heat dissipation is not uniform. In the present disclosure, the piezoelectric element is used to perform work on air, so that the air obtains a forward initial velocity, and flows through the jet holes 160 to create air jets. The jet holes may be evenly provided in the entire region of the jet plate 150, so that the heat dissipation area is greatly increased, thereby improving the heat dissipation effect and ensuring uniform heat dissipation.

3. High flow rate and high energy utilization rate: A conventional synthetic jet plate 150 is generally provided with one or several jet holes 160 only in a middle portion thereof, and the overall efficiency is low. In the present disclosure, a large number of jet holes 160 are arranged in the entire region of the jet plate 150, so that the system energy is fully utilized, thereby achieving a high energy utilization rate and a good heat dissipation effect.

4. High back pressure and high heat dissipation efficiency: In the present disclosure, the piezoelectric element is used to perform work on air to drive the air to flow directionally, and the back pressure generated by the piezoelectric element is ten times or more that of a conventional cooling fan, so that higher heat dissipation efficiency is achieved.

5. Reasonable structure: With the structural design of the heat dissipation system, cooling air is sucked in from the cold end, and is ejected from the other end far from the cold end to the heat generating element 300 for heat dissipation. Such a structural design achieves high heat exchange efficiency and can further improve the heat dissipation effect.

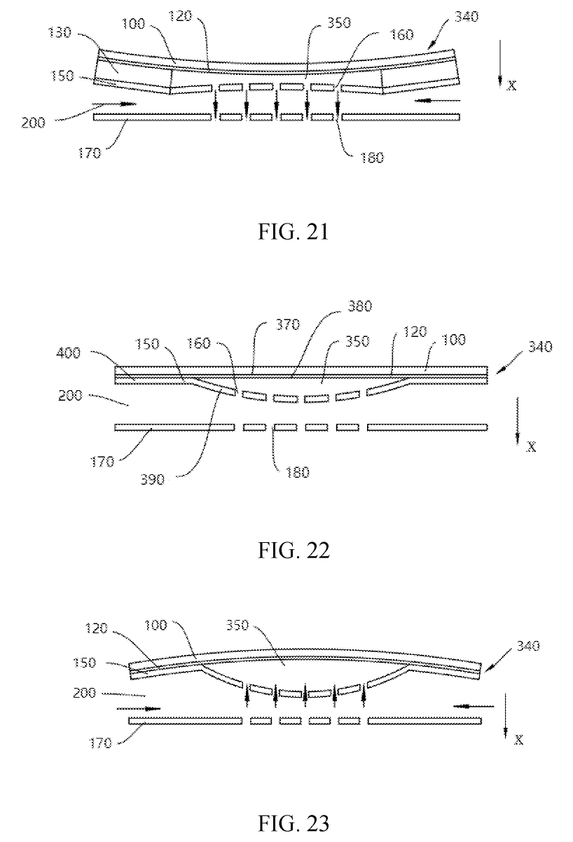

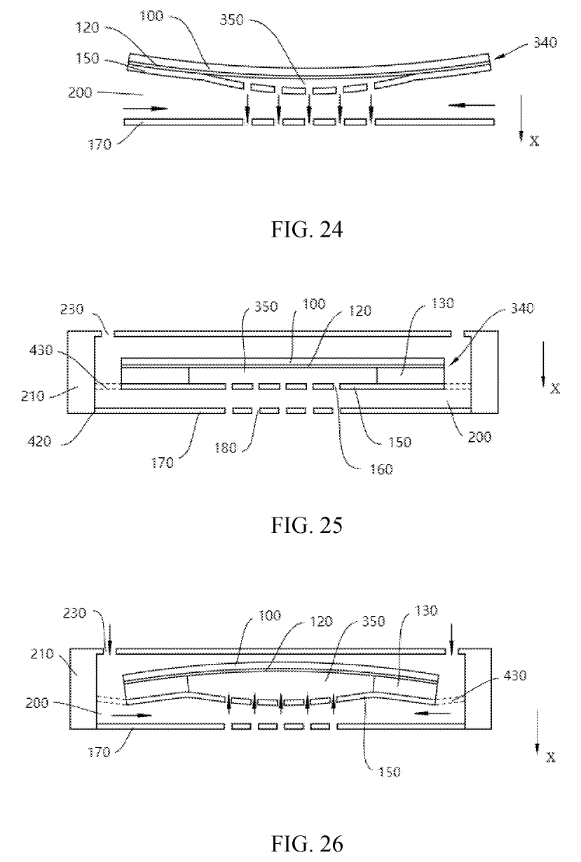

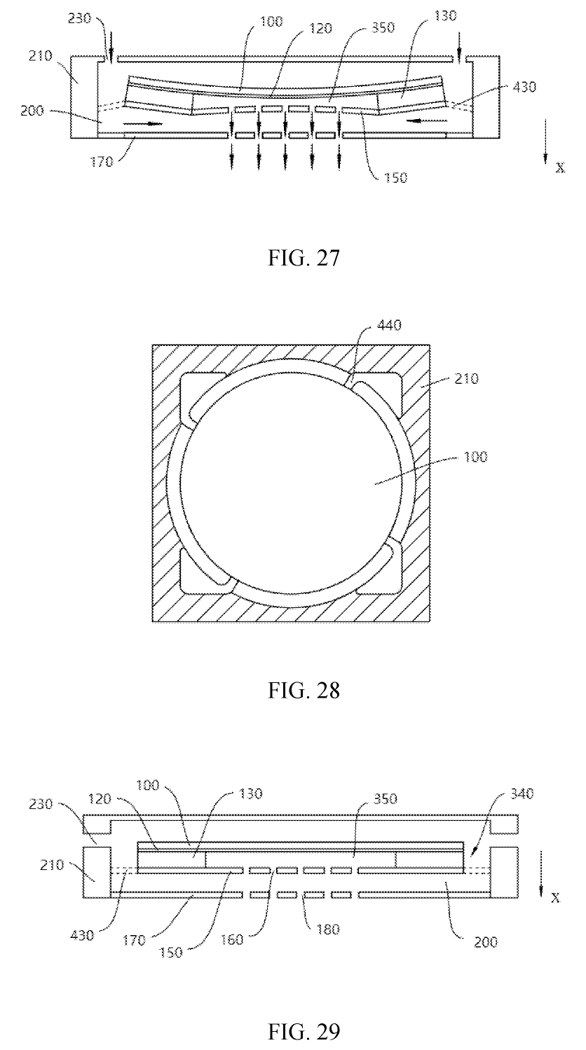

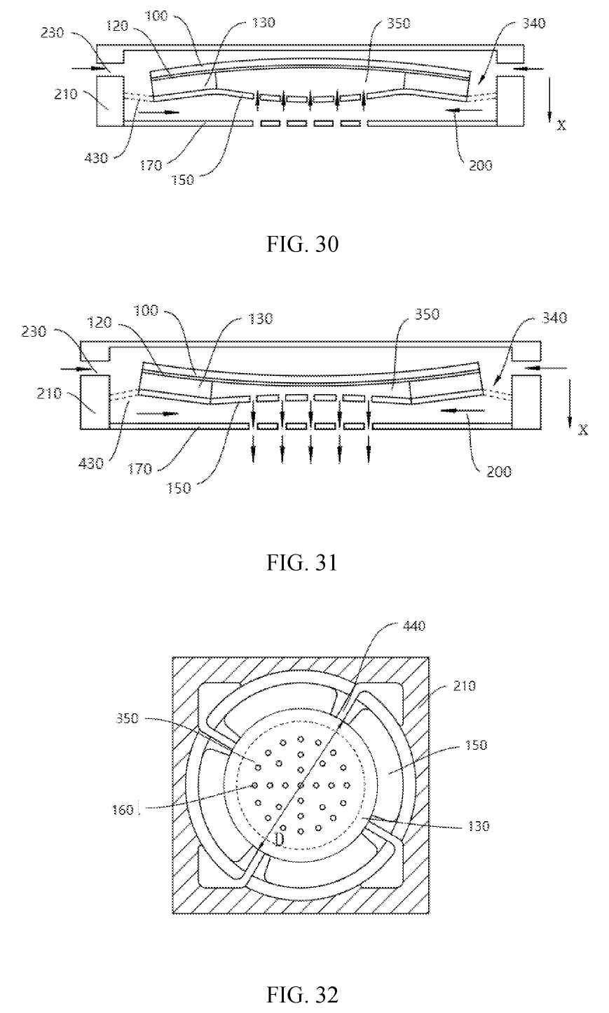

Referring to FIG. 19 to FIG. 40, the present disclosure proposes improvements in a second aspect to further improve the structural design, heat dissipation efficiency, reliability, and the like.

A first side surface 370 and a second side surface 380 are shown in FIG. 19.

### Embodiment One of the second aspect of the present disclosure:

Referring to FIG. 19 to FIG. 21, the piezoelectric element 100 is fixed to the diaphragm 120. The piezoelectric element 100 may be an independent piezoelectric crystal, which, together with the diaphragm 120, constitutes a transducer capable of generating a bending vibration; may be a piezoelectric unimorph consisting of a piezoelectric crystal and an elastic substrate; may be a piezoelectric bimorph formed by attaching piezoelectric crystals to two surfaces of an elastic substrate; or may be a piezoelectric laminate formed by bonding of two piezoelectric crystals and capable of generating a bending vibration. In other words, the piezoelectric element 100 needs to be capable of driving the diaphragm 120 to generate a bending deformation vibration. The first piezoelectric element 280 may be of any structural shape, e.g., circular, square, annular, etc., which is not limited herein. The piezoelectric crystal may be a multilayer piezoelectric ceramic or a single-layer piezoelectric ceramic.

An edge of the jet plate 150 is connected to the diaphragm 120 through a support frame 130. The jet plate 150 is provided with a plurality of jet holes 160 in a middle portion thereof. The jet holes 160 are generally circular, or may be rectangular, waist-shaped, elliptical, arc-shaped, or in other shapes. An equivalent diameter of a single jet hole 160 may be 50 μm to 500 um. The number of the jet holes 160 is determined by the total area of the jet plate 150 and the area of a single jet hole 160. The total area of the jet holes 160 accounts for 0.1% to 10% of the total area of the jet plate 150. In some embodiments, the number of the jet holes 160 is 5 to 200.

The diaphragm 120 may be a metal film made of stainless steel, copper, aluminum alloy, titanium alloy, etc., or may be a non-metal film made of polyimide, PET, epoxy resin, rubber, etc., and may have a thickness ranging from 0.01 mm to 1 mm.

An outer diameter of the piezoelectric element 100 may be larger than an outer diameter of the energy conversion cavity 350.

A dimension of the support frame 130 in the first direction x is defined as h₁. To prevent the vibration of the middle portion of the jet plate 150 from interfering with the vibration of the diaphragm 120, h₁ is greater than a sum of a maximum downward amplitude of the diaphragm 120 and a maximum upward amplitude of the middle portion of the jet plate 150. In some embodiments, h₁ ranges from 20 μm to 500 μm.

The air exit plate 170 is provided with a plurality of air exit holes 180 for air to pass through. The air exit holes 180 may or may not correspond one-to-one to the jet holes 160. For example, a plurality of air exit holes 180 may be combined into one air exit hole 180 for air ejected from the jet holes 160 to pass through. Generally, the size of the air exit hole 180 is larger than the size of the jet hole 160, or may be equal to or smaller than the size of the jet hole 160, which may be adjusted according to a required flow rate and noise level. In some embodiments, the total area of the air exit holes 180 accounts for 1% to 20% of the total area of the air exit plate 170.

A distance between the jet plate 150 and the air exit plate 170 in the first direction x is defined as h₂, which affects the magnitude of the flow rate of air entering the air inlet 230, and also affects the magnitude of the flow rate of air carried away during entrainment of air jets. The value of h₂ may be adjusted according to requirements. In some embodiments, h₂ ranges from 0.1 mm to 2 mm.

In this embodiment, the piezoelectric element 100 is directly fixed to the diaphragm 120, and together with the diaphragm 120, constitutes a transducer capable of generating a bending vibration. The piezoelectric element 100 utilizes the piezoelectric effect to drive the composite structure of the diaphragm and the jet plate to reciprocate, to realize the periodic compression and expansion of the air in the pump cavity to form a directional airflow. The piezoelectric heat dissipation device does not require the complex mechanical structure of a conventional fan, and is easy to miniaturize.

### Embodiment Two of the second aspect of the present disclosure:

Referring to FIG. 22 to FIG. 24, similar to the overall structure of the piezoelectric heat dissipation device of Embodiment One, the piezoelectric heat dissipation device of this embodiment includes the piezoelectric element 100, the diaphragm 120, the jet plate 150, and the air exit plate 170.

Different from Embodiment One, a curved structure protruding away from the second side surface along the first direction is formed in a middle portion of the jet plate 150, the curved structure is often referred to as a “cymbal-shaped” structure, an annular structure extending outward is formed at an edge of the curved structure, the annular structure is connected to an edge of the second side surface, and the energy conversion cavity is defined by the curved structure and the second side surface; and/or

the piezoelectric heat dissipation device further includes a support frame, an edge of the second side surface is connected to the jet plate 150 through the support frame, and the energy conversion cavity is defined by the second side surface, the support frame, and the jet plate 150.

In this embodiment, the jet plate 150 adopts a curved structure, and an edge of the jet plate 150 is connected to the diaphragm 120 without using the support frame 130, the middle portion of the jet plate 150 is a concave curved structure 390, the edge of the jet plate 150 is an annular structure extending outward, and a plurality of jet holes 160 are distributed in the curved structure 390.

By such a configuration, the jet plate 150 can increase the displacement of bending deformation, and increase the volume change of the energy conversion cavity 350, thereby increasing the air volume of the piezoelectric heat dissipation device.

### Embodiment Three of the second aspect of the present disclosure:

This embodiment describes a piezoelectric heat dissipation device structure with an air inlet at the top and an air outlet at the bottom.

As shown in FIG. 25 to FIG. 28, the piezoelectric heat dissipation device structure basically includes a housing 210 and a piezoelectric heat dissipation device. The housing 210 is the same as that in Embodiment One, and includes a piezoelectric assembly 340 and an air exit plate 170. The working principle of the housing 210 is the same as that in Embodiment One.

In this embodiment, the piezoelectric assembly 340 is connected to the housing 210 through an elastic assembly 430 to reduce the vibration of the housing 210 and improve the heat dissipation efficiency.

The air inlet 230 is provided at a top of the housing 210. The air inlet 230 is in communication with the intake passage 200. Air enters from the air inlet 230 at the top, and finally flows out from the air outlet 470 at the bottom. Thus, a structure with an air inlet at the top and an air outlet at the bottom is formed.

### Embodiment Four of the second aspect of the present disclosure:

This embodiment describes a piezoelectric heat dissipation device structure with an air inlet on a side surface and an air outlet at the bottom.

As shown in FIG. 29 to FIG. 31, the structure of the piezoelectric heat dissipation device of this embodiment is the same as that of the piezoelectric heat dissipation device in Embodiment Three, except that the air inlet 230 is provided on a side surface of the housing 210. The piezoelectric heat dissipation device of this embodiment is applicable to application occasions where the mounting space is low and it is inconvenient to provide a hole at the top.

### Embodiment Five of the second aspect of the present disclosure:

During operation of the piezoelectric heat dissipation device, the entire energy conversion cavity 350 vibrates, and the vibration will be transmitted to the housing 210 through the connection therebetween, leading to energy loss. To reduce this part of energy loss, the energy conversion cavity 350 is connected to the housing through an elastic assembly 430.

Referring to FIG. 32, in this embodiment, the piezoelectric assembly 340 is connected to the housing 210 through four elastic cantilevers 440, where a fixed end of each cantilever is connected to the housing, and a free end of each cantilever is connected to an outer wall of the energy conversion cavity 350. Specifically, the free end may be connected to an edge of the jet plate 150 or may be connected to an outer peripheral wall of the support frame 130. The connection points between the plurality of elastic cantilevers 440 and the outer wall of the energy conversion cavity 350 lie on a circumference with a diameter D. When the diameter D is equal to 1/2 wavelength of the driving frequency, the diameter D will be exactly on a wave node of the vibration of the energy conversion cavity 350. In this case, the amplitude of the elastic cantilevers 440 is zero, i.e., the cantilevers do not vibrate and do not transmit vibration to the housing 210. As such, the system energy loss is minimized and the efficiency is maximized.

### Embodiment Six of the second aspect of the present disclosure:

In some application scenarios, it is inconvenient to provide the air outlet 470 at the bottom, and air needs to be discharged from a side surface. This embodiment describes a piezoelectric heat dissipation device applicable to scenarios where air needs to be discharged from a side surface.

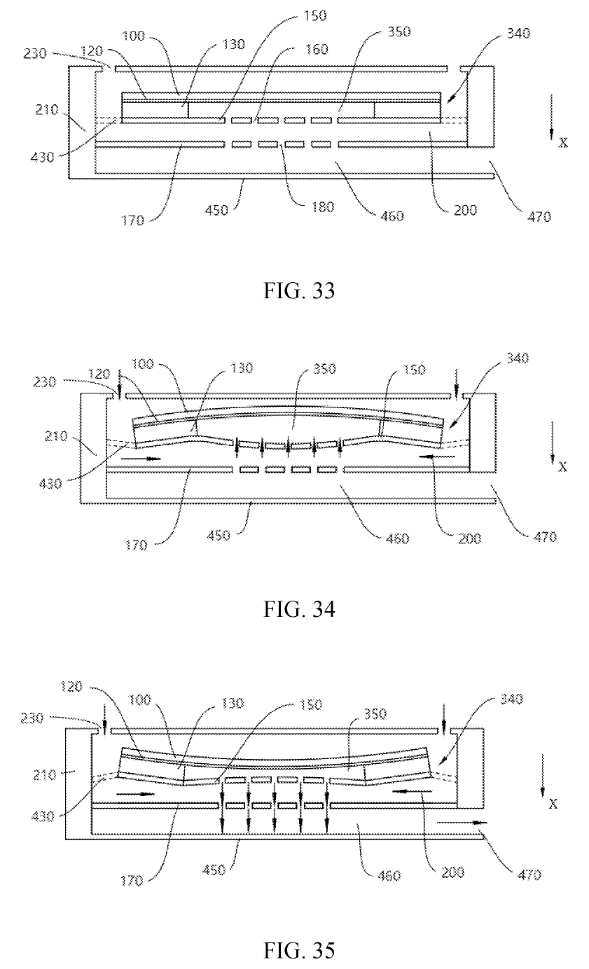

As shown in FIG. 33 to FIG. 35, the piezoelectric heat dissipation device basically includes a housing 210, a piezoelectric assembly 340, and an air exit plate 170. The piezoelectric assembly 340 in this embodiment is the same as that in Embodiment One. The piezoelectric assembly 340 is connected to the housing 210 through an elastic assembly 430 to reduce the vibration of the housing 210 and improve the heat dissipation efficiency.

A baffle plate 450 is arranged below the air exit plate 170. An outlet passage 460 is defined by the air exit plate 170 and the baffle plate 450. Air flows out from the air exit holes 180 to the outlet passage 460, turns upon hitting the baffle plate 450, and finally flows out from an air outlet 470 on a side surface.

The air inlet 230 is provided at a top of the housing 210. The air inlet 230 is in communication with the intake passage 200. Air enters from the air inlet 230 at the top, and finally flows out from the air outlet 470 at the side surface. Thus, a structure with an air inlet at the top and an air outlet on a side surface is formed.

### Embodiment Seven of the second aspect of the present disclosure:

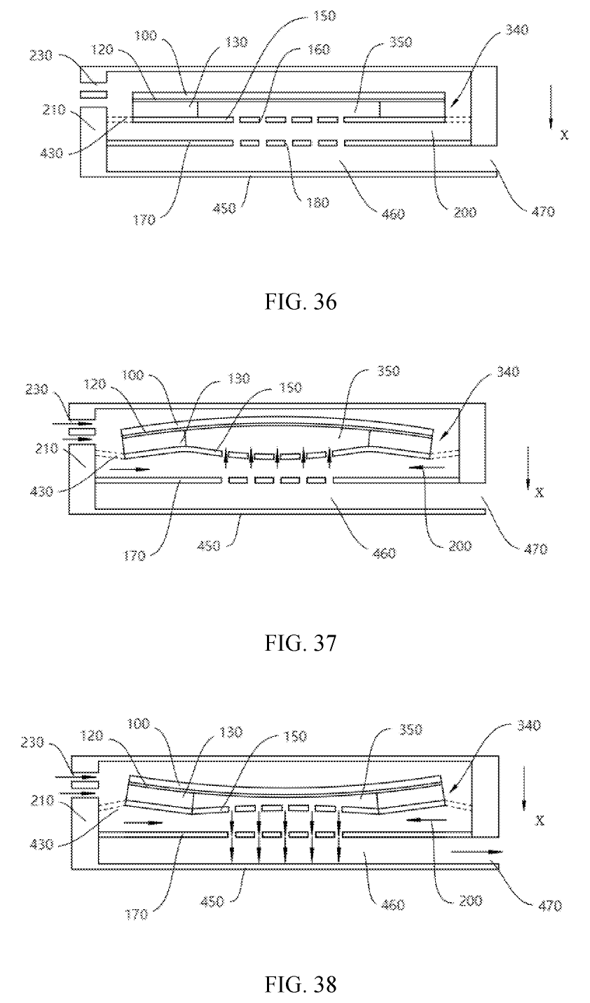

As shown in FIG. 36 to FIG. 38, the structure of the piezoelectric heat dissipation device of this embodiment is the same as that of the piezoelectric heat dissipation device in Embodiment Six, except that the air inlet 230 is provided on a side surface of the housing 210. The piezoelectric heat dissipation device of this embodiment has a structure with an air inlet on a side surface and an air outlet on a side surface, and is applicable to application occasions where it is inconvenient to provide holes at the top and bottom.

### Embodiment Eight of the second aspect of the present disclosure:

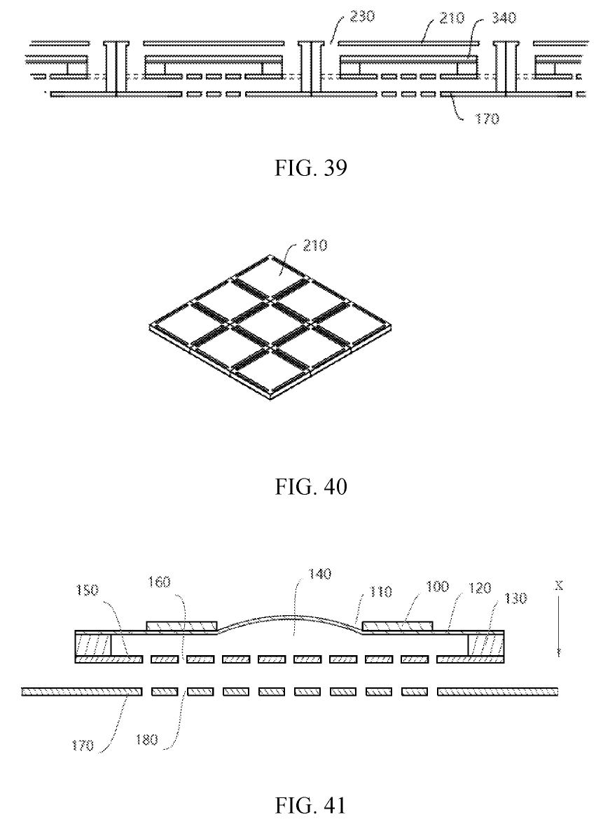

As shown in FIG. 39 and FIG. 40, each piezoelectric heat dissipation device has the same structure as the piezoelectric heat dissipation device in Embodiment Three, and includes a housing, an air exit plate 170, an elastic assembly 430, and a piezoelectric assembly 340. As an expanded scheme, a plurality of piezoelectric heat dissipation devices are arranged to form a heat dissipation system. Because the flow rate and the heat dissipation area of the entire heat dissipation system is the sum of the flow rates and the heat dissipation areas of the plurality of piezoelectric heat dissipation devices, the theoretical flow rate and heat dissipation area of the heat dissipation system may be designed according to actual requirements. Therefore, the heat dissipation system is suitable for occasions requiring a high flow rate and a large heat dissipation area that cannot be satisfied by a single piezoelectric heat dissipation device. In addition, the heat dissipation system is easy to deploy and easy to use.

Based on the above, the embodiments of the present disclosure provide a piezoelectric heat dissipation device, which has the following advantages.

1. Thin structure: The intake passage 200 is provided between the jet plate 150 and the air exit plate 170, and is located on the side surface of the piezoelectric heat dissipation device. When the piezoelectric heat dissipation device is mounted for use, only an air intake space in the horizontal direction needs to be reserved, which can reduce the requirements for the size of the space in the vertical direction. Therefore, piezoelectric heat dissipation device is suitable for heat dissipation of thin electronic products.

2. High heat dissipation efficiency: The intake passage 200 is located between the jet plate 150 and the air exit plate 170, and is closer to the jet holes 160 and the air exit holes 180. Air enters from the intake passage 200 and is discharged through the air exit holes 180. In the whole process, the flow path along which the air flows is shorter, the energy loss during the air flow is smaller, and the heat dissipation efficiency is higher. In addition, the jet plate 150 is designed to have a curved structure, which can further increase the displacement of bending deformation, and increase the volume change of the energy conversion cavity 350, thereby increasing the air volume of the piezoelectric heat dissipation device.

3. Reasonable structure: With the structural design of the heat dissipation system, cooling air is sucked in from the cold end, and is ejected from the other end far from the cold end to the heat generating elements for heat dissipation. Such a structural design achieves high heat exchange efficiency and can further improve the heat dissipation effect.

4. High energy efficiency: The piezoelectric assembly 340 is connected to the housing 210 through an elastic assembly 430 to reduce the vibration of the housing 210 and improve the heat dissipation efficiency, thereby reducing energy loss.

Referring to FIG. 41 to FIG. 52, the present disclosure proposes improvements in a third aspect, and provides a durable and highly reliable piezoelectric heat dissipation device to cope with the problem of fatigue failure caused by continuous vibration.

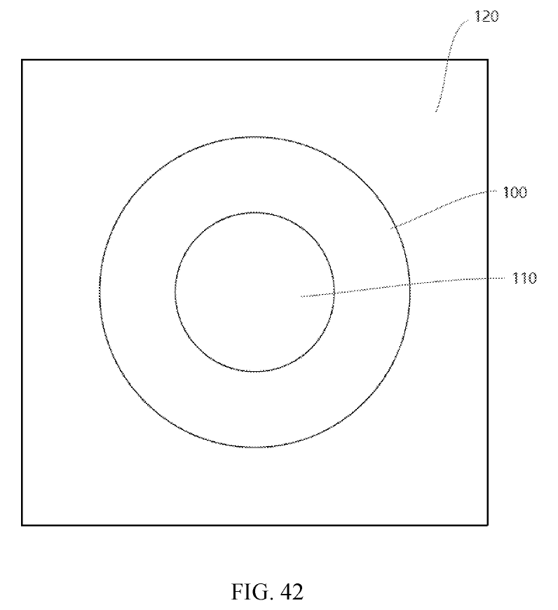

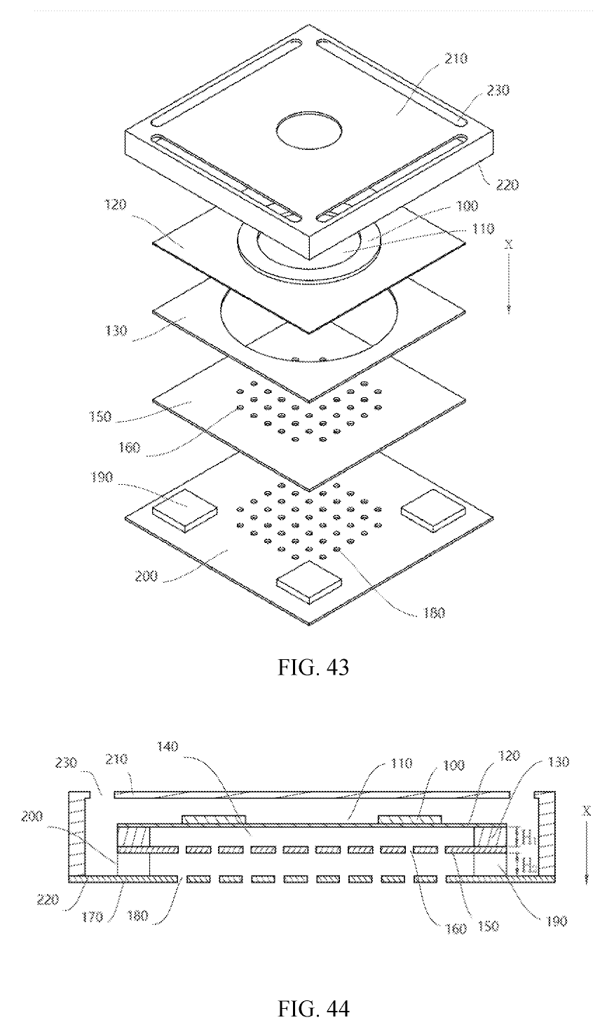

Referring to FIG. 41, FIG. 42, and FIG. 43, an embodiment of the present disclosure provides a piezoelectric heat dissipation device, which includes a piezoelectric element 100, a diaphragm 120, a support frame 130, a jet plate 150, and an air exit plate 170.

The support frame 130 is provided with an energy conversion cavity 140 which is open on two sides thereof in a first direction x. The diaphragm 120 and the jet plate 150 are respectively arranged to cover the two sides of the energy conversion cavity 140 in the first direction x and are connected to the support frame 130. The jet plate 150 is provided with jet holes 160. The piezoelectric element 100 is attached to a side of the diaphragm 120 facing away from the energy conversion cavity 140 in the first direction x and/or a side of the jet plate 150 facing away from the energy conversion cavity 140 in the first direction x. The piezoelectric element 100 is provided with a central hole 110. The air exit plate 170 is arranged spaced apart from the side of the jet plate 150 facing away from the energy conversion cavity 140 in the first direction x. The air exit plate 170 is provided with air exit holes 180 in communication with the jet holes 160.

The piezoelectric element 100 includes a first piezoelectric element 280 and/or a second piezoelectric element 290. The first piezoelectric element 280 is arranged on the diaphragm 120. To be specific, the first piezoelectric element 280 is arranged on a side of the diaphragm 120 facing away from the energy conversion cavity 140 in the first direction x. The second piezoelectric element 290 is attached to the jet plate 150. To be specific, the second piezoelectric element 290 is attached to the side of the jet plate facing away from the energy conversion cavity 140 in the first direction x.

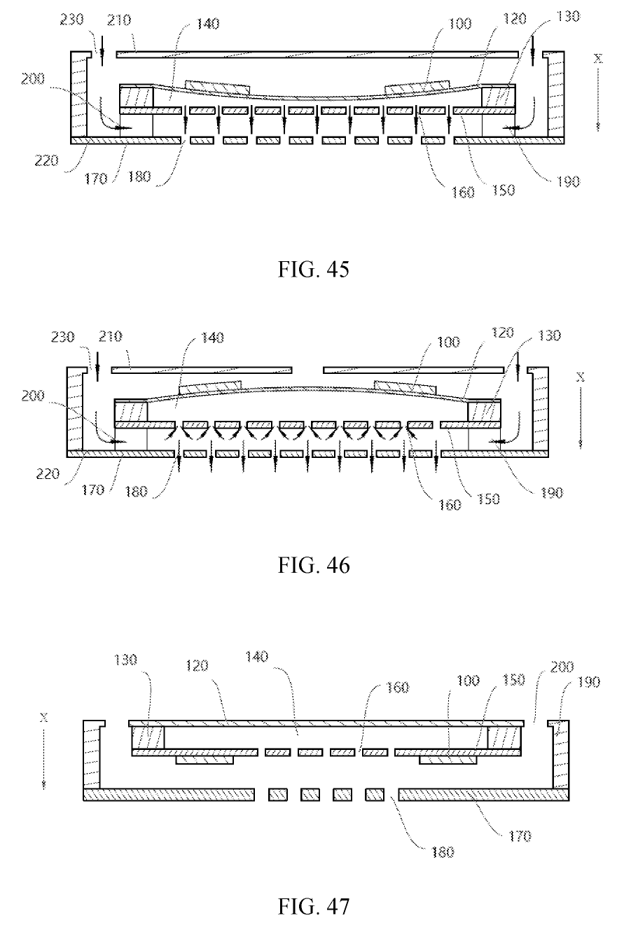

Specifically, the operation process of the piezoelectric heat dissipation device is similar to that of the first aspect of the present disclosure, so the details will not be repeated herein. For details, reference can be made to FIG. 45 and FIG. 46.

As shown in FIG. 42, in some improved schemes of the third aspect of the present disclosure, a projection of the piezoelectric element 100 in the first direction x is circular, and the central hole 110 is a circular hole. The circular structure is stressed more uniformly during vibration, which can further reduce stress concentration and prolong the service life of the piezoelectric element 100.

In some improved schemes of the third aspect of the present disclosure, the piezoelectric element 100 is attached to the side of the jet plate 150 facing away from the energy conversion cavity 140 in the first direction x, and projections of the jet holes 160 in the first direction x all fall within the central hole 110. As such, air can directly pass through the central hole 110, and there is no need to provide holes at other positions on the piezoelectric element 100.

Referring to FIG. 44, in some improved schemes of the third aspect of the present disclosure, a spacing dimension between the diaphragm 120 and the jet plate 150 in the first direction x is defined as H₁, where 0.02 mm≤H₁≤0.5 mm. In other words, a dimension from the diaphragm 120 to the jet plate 150 in the first direction x is a height H₁ of the energy conversion cavity 140. To prevent the jet plate 150 from interfering with the vibration of the diaphragm 120, H₁ needs to be greater than a maximum amplitude of the diaphragm 120 or the jet plate 150. The closer the jet plate 150 is to the diaphragm 120, the higher the energy obtained by the air, and the larger the initial velocity of the air.

In some improved schemes of the third aspect of the present disclosure, a spacing dimension between the jet plate 150 and the air exit plate 170 in the first direction x is defined as H₂, where 0.1 mm≤H₂≤2 mm. In other words, a distance between the jet plate 150 and the air exit plate 170 is defined as H₂, which affects the magnitude of the flow rate of air entering the energy conversion cavity 140 from a gap between the jet plate 150 and the air exit plate 170, and also affects the magnitude of the flow rate of air carried away during entrainment of air jets from the jet holes 160. The value of H₂ may be adjusted according to a required flow rate and noise level. In some embodiments, H₂ ranges from 0.1 mm to 2 mm.

In some improved schemes of the third aspect of the present disclosure, the jet holes 160 are circular holes, and the jet holes 160 have a diameter ranging from 0.005 mm to 0.5 mm. The design of the circular hole ensures that air passes through evenly and reduces local turbulence. The design of the jet holes 160 having a small diameter can increase the airflow speed and enhance the heat dissipation effect.

In some improved schemes of the third aspect of the present disclosure, the jet plate 150 is provided with a plurality of jet holes 160, the air exit plate 170 is provided with a plurality of air exit holes 180, diameters of the air exit holes 180 are larger than diameters of the jet holes 160, and in the first direction x, one air exit hole 180 is arranged corresponding to at least one jet hole 160. Generally, the air exit holes 180 may or may not correspond one-to-one to the jet holes 160. For example, a plurality of air exit holes 180 may be combined into one air exit hole 180 for air from a plurality of jet holes 160 to pass through. Generally, the size of the air exit hole 180 is larger than the size of the jet hole 160, or in some other embodiments, may be equal to or smaller than the size of the jet hole 160, which may be adjusted according to a required flow rate and noise level. By increasing the area ratio of the air exit hole 180 to the corresponding jet hole(s) 160, the rate of change of the airflow speed can be reduced, thereby reducing the noise generated when the air flow passes through the air exit holes 180.

In some improved schemes of the third aspect of the present disclosure, the jet plate 150 is provided with a plurality of jet holes 160, where an area of a projection of the jet plate 150 in the first direction x is defined as S₁, a total area of projections of the jet holes 160 in the first direction x is defined as S₂, and 0.1%≤S₂/S₁≤10%. The jet holes 160 are evenly distributed on the jet plate 150. The jet holes 160 are generally circular, or may be rectangular, waist-shaped, elliptical, or in other shapes. A diameter of a single jet hole 160 may be 5 μm to 500 um. The number of the jet holes 160 is determined by the total area of the jet plate 150 and the area of a single jet hole 160. The total area of the jet holes 160 accounts for 0.1% to 10% of the total area of the jet plate 150. In some embodiments, the number of the jet holes 160 is 10 to 2000.

In some improved schemes of the third aspect of the present disclosure, the air exit plate 170 is provided with a plurality of air exit holes 180, where an area of a projection of the air exit plate 170 in the first direction x is defined as S₃, a total area of projections of the air exit holes 180 in the first direction x is defined as S₄, and 1%≤S₄/S₃≤20%. The air exit holes 180 on the air exit plate 170 are configured for air ejected from the jet holes 160 to pass through, to ensure that heat can be quickly dissipated. In some embodiments, the total area of the air exit holes 180 accounts for 1% to 20% of the total area of the air exit plate 170.

In some improved schemes of the third aspect of the present disclosure, the piezoelectric heat dissipation device further includes a first connection assembly 190;

the air exit plate 170 is connected to an edge of the jet plate 150 through the first connection assembly 190, or the air exit plate 170 is connected to an edge of the diaphragm 120 through the first connection assembly 190; and

the first connection assembly 190 is provided with an intake passage 200 in communication with the jet holes 160.

In some improved schemes of the third aspect of the present disclosure, the piezoelectric heat dissipation device further includes a housing 210, the housing 210 is provided with a window 220 on one side thereof in the first direction x, the air exit plate 170 is arranged to cover the window 220. The piezoelectric element 100, the diaphragm 120, the support frame 130, and the jet plate 150 are arranged in the housing 210, and the housing 210 is provided with an air inlet 230 in communication with the intake passage 200.

In some improved schemes of the third aspect of the present disclosure, the air inlet 230 is provided on a side of the housing 210 facing away from the window 220 in the first direction x. The air inlet 230 and the window 220 are arranged opposite to each other in the first direction x, i.e., the air inlet 230 and the air exit holes 180 are arranged opposite to each other, to prevent the ejected air from being sucked into the piezoelectric heat dissipation device, thereby improving the efficiency of heat dissipation cycles.

As shown in FIG. 44 to FIG. 46, in a first embodiment of the present disclosure, the piezoelectric element 100 is attached to the diaphragm 120. As shown in FIG. 44, the piezoelectric heat dissipation device includes, in the first direction x from top to bottom, a housing 210, a piezoelectric element 100, a diaphragm 120, a support frame 130, a jet plate 150, a first connection assembly 190, and an air exit plate 170, which are fixed by welding or an adhesive. The housing 210 is made of a metal or plastic material and is provided with an air inlet 230. In this embodiment, the diaphragm 120 is rectangular, and a periphery of the diaphragm 120 and a periphery of the jet plate 150 are both fixed to the support frame 130. In some other embodiments, the diaphragm 120 may be circular or in other shapes. The jet plate 150 is provided with a plurality of jet holes 160 evenly distributed in a hollow region in the middle of the energy conversion cavity 140. Another side of the jet plate 150 is fixed to the first connection assembly 190, and an intake passage 200 for intake of air is provided around the first connection assembly 190. The air exit plate 170 is located on another side of the first connection assembly 190. An air outlet is provided on the air exit plate 170. The air exit plate 170 is further connected to the housing 210.

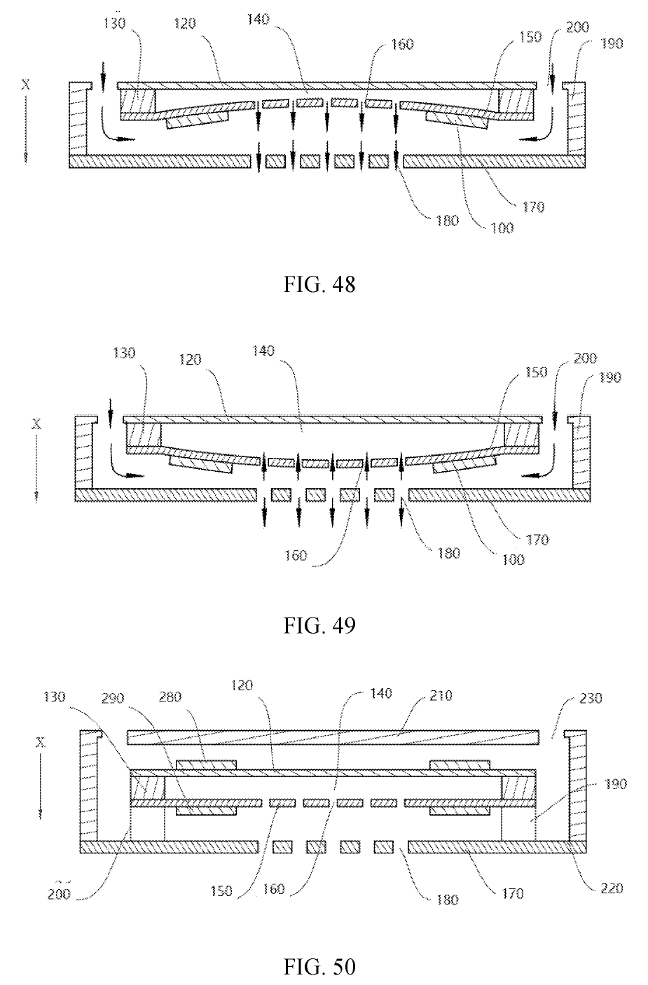

As shown in FIG. 47 and FIG. 48, in a second embodiment of the present disclosure, the piezoelectric element 100 is attached to the jet plate 150. As shown in FIG. 47, the piezoelectric heat dissipation device includes a diaphragm 120, a support frame 130, a jet plate 150, a piezoelectric element 100, and an air exit plate 170 in sequence from top to bottom. Its basic structure is the same as that of the first embodiment, and its working principle is similar to that of the first embodiment. In this embodiment, the diaphragm 120 substantially undergoes no deformation and can be regarded as a cover plate, the air exit plate 170 is connected to the diaphragm 120 through a first connection assembly 190, and the first connection assembly 190 is provided with an intake passage 200 in communication with the jet holes 160. The piezoelectric element 100 is fixed to the jet plate 150. When a driving voltage is applied to the piezoelectric element 100, the piezoelectric element 100 vibrates and drives the jet plate 150 to vibrate. The jet plate 150 also serves as a vibrating element. Therefore, compared with the first embodiment, the structure of this embodiment is simpler, and the dimension of the piezoelectric heat dissipation device as a whole in the first direction x is smaller, so this embodiment is more suitable for use in a narrow heat dissipation space. In addition, the piezoelectric element 100 can drive air to be discharged in the process of driving the jet plate 150 to deform upward or downward, so that higher efficiency is achieved. In some specific embodiments, an overall thickness of the piezoelectric heat dissipation device may be as small as 0.5 mm to 1.0 mm.

FIG. 48 and FIG. 49 show an operation process of the piezoelectric heat dissipation device. The principle of the piezoelectric heat dissipation device is similar to that of the first embodiment, and has higher efficiency than that of the first embodiment.

As shown in FIG. 50 to FIG. 52, in a third embodiment of the present disclosure, a piezoelectric element 100 is attached to each of the jet plate 150 and the diaphragm 120, so that the performance of the piezoelectric heat dissipation device can be greatly increased without increasing the overall size of the piezoelectric heat dissipation device. The basic structure of the piezoelectric heat dissipation device of this embodiment is the same as that of the first embodiment, and includes a housing 210, a piezoelectric element 100, a diaphragm 120, a support frame 130, a jet plate 150, and an air exit plate 170. The working principle of the piezoelectric heat dissipation device of this embodiment is the same as that of the first embodiment, and has all the advantages of the first embodiment.

Different from the first embodiment, in this embodiment, a piezoelectric element 100 is also fixed to the jet plate 150, and during operation, driving voltages are respectively applied to the two piezoelectric elements 100, so that the diaphragm 120 and the jet plate 150 generate vibrations with the same frequency and opposite directions. Because the diaphragm 120 and the jet plate 150 vibrate at the same frequency and in opposite directions, the volume change rate of the energy conversion cavity 140 is greatly improved compared to that in the first embodiment. This greatly increases the ability to drive the air, thereby greatly increasing the performance of the piezoelectric heat dissipation device.

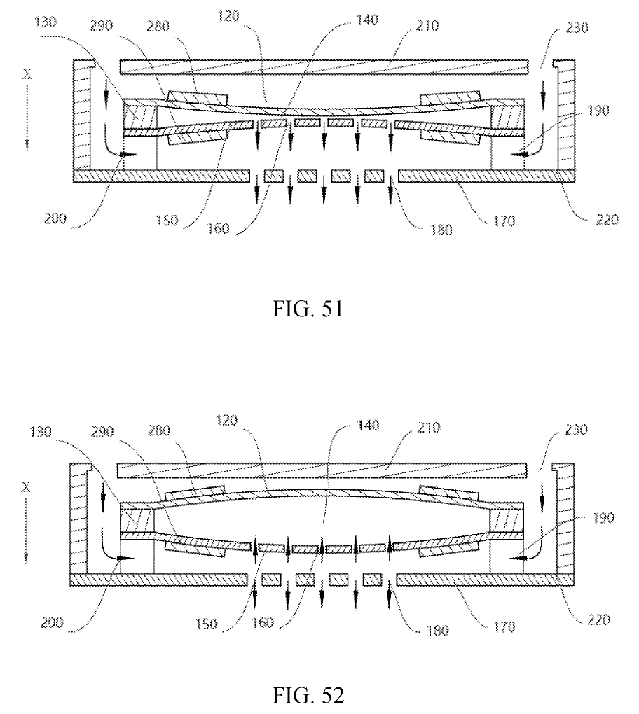

Referring to FIG. 51, the air in the energy conversion cavity 140 is greatly compressed to achieve a forward initial velocity, and the air flows outward through the jet holes 160 on the jet plate 150 to create air jets, which form a vortex pair and entrain air nearby, and finally the air is discharged through the air exit holes 180.

Referring to FIG. 52, as the volume of the energy conversion cavity 140 increases, the pressure in the energy conversion cavity 140 decreases, outside air enters the energy conversion cavity 140, and part of the air is discharged through the air exit holes 180.

Based on the above, the embodiments of the present disclosure provide a piezoelectric heat dissipation device, in which a piezoelectric element 100 is provided with a central hole 110, and when a voltage is applied to drive the piezoelectric element 100 to deform, the deformation of the piezoelectric element 100 can be reduced and can be amplified by the diaphragm 120 or the jet plate 150 arranged at the central hole 110, to drive air to flow. Because the amount of deformation of the piezoelectric element 100 is small, the generation of fatigue cracks due to long-term operation is effectively avoided, thereby significantly extending the service life of the piezoelectric heat dissipation device.

While exemplary embodiments of the present disclosure have been described above, the present disclosure is not limited thereto. It should be appreciated that some improvements and replacements can be made by those having ordinary skills in the art without departing from the technical principles of the present disclosure, which are also contemplated to be within the protection scope of the present disclosure.

What is claimed is:

1. A piezoelectric heat dissipation device, comprising: a housing, a second connection assembly, and a piezoelectric assembly, wherein:
the piezoelectric assembly is arranged in the housing and is connected to the housing through the second connection assembly, the piezoelectric assembly comprises a first piezoelectric element, a diaphragm, a support frame, and a jet plate connected in sequence along a first direction, the jet plate is provided with jet holes, and an energy conversion cavity in communication with the jet holes is defined by the diaphragm, the support frame, and the jet plate; and
the housing comprises a housing body and an air exit plate, the housing body is provided with a first opening facing the jet plate in the first direction, the air exit plate is arranged to cover the first opening, the air exit plate is provided with air exit holes in communication with the jet holes, and the housing body is further provided with an air inlet in communication with the jet holes.

2. The piezoelectric heat dissipation device of claim 1, wherein:
one side of the second connection assembly is connected to an edge of the jet plate, another side of the second connection assembly is connected to the air exit plate, the second connection assembly is provided with an intake passage, and the air inlet is in communication with the jet holes through the intake passage; and/or
one side of the second connection assembly is connected to an outer peripheral wall of the piezoelectric assembly in the first direction, another side of the second connection assembly is connected to an inner peripheral wall of the housing body in the first direction, the second connection assembly is provided with an intake passage, and the air inlet is in communication with the jet holes through the intake passage.

3. The piezoelectric heat dissipation device of claim 1, wherein one side of the second connection assembly is connected to an edge of the diaphragm, and another side of the second connection assembly is connected to an inner wall of the housing body facing the diaphragm in the first direction.

4. The piezoelectric heat dissipation device of claim 1, wherein the second connection assembly comprises at least two elastic supporting members, the at least two elastic supporting members are connected to the piezoelectric assembly and the housing, and the at least two elastic supporting members are arranged at intervals along a circumferential direction of the piezoelectric assembly; and/or
the piezoelectric heat dissipation device comprises a plurality of piezoelectric assemblies, the piezoelectric assembly is one of the plurality of piezoelectric assemblies, and the plurality of piezoelectric assemblies are arranged at intervals in a direction perpendicular to the first direction.

5. A heat dissipation system, comprising one or more piezoelectric heat dissipation devices, each of the one or more piezoelectric heat dissipation devices being the piezoelectric heat dissipation device of claim 1, wherein the one or more piezoelectric heat dissipation devices are arranged at intervals in a direction perpendicular to the first direction, outer peripheral walls of neighboring housing bodies are connected to each other, and the air inlet is provided on a side of the housing body facing away from the first opening in the first direction.

6. The heat dissipation system of claim 5, further comprising a heat generating element, wherein the air inlet is provided on the side of the housing body facing away from the first opening in the first direction, and the heat generating element is arranged spaced apart from a side of the piezoelectric heat dissipation device facing the air exit plate in the first direction; and/or
further comprising a heat generating element, a heat-conducting plate, and a supporting member, wherein the heat-conducting plate comprises a hot end and a cold end opposite to the hot end in a second direction, the heat generating element is pressed against the hot end, the piezoelectric heat dissipation device is arranged spaced apart from the cold end in the first direction, one side of the supporting member is connected to the heat-conducting plate, another side of the supporting member is connected to an edge of the piezoelectric heat dissipation device, an outlet passage is defined by the air exit plate, the supporting member, and the heat-conducting plate, an air outlet is provided on one side of the supporting member adjacent to the cold end in the second direction, and the air outlet is in communication with the outlet passage; the air inlet is provided on the side of the housing body facing away from the first opening in the first direction, or on a side of the housing body facing away from the air outlet in the second direction; and
the second direction is perpendicular to the first direction.

7. A piezoelectric heat dissipation device, comprising: a piezoelectric assembly and an air exit plate, wherein the piezoelectric assembly comprises a piezoelectric element, a diaphragm, and a jet plate, wherein:
the diaphragm has a first side surface and a second side surface opposite to the first side surface in a first direction, the piezoelectric element is attached to the first side surface, the jet plate protrudes away from the second side surface in the first direction, an energy conversion cavity is defined by the jet plate and the second side surface, the jet plate is provided with jet holes in communication with the energy conversion cavity, the air exit plate is arranged spaced apart from a side of the jet plate facing away from the energy conversion cavity in the first direction, an intake passage in communication with the jet holes is formed between the air exit plate and the jet plate, and the air exit plate is provided with air exit holes in communication with the jet holes.

8. The piezoelectric heat dissipation device of claim 7, wherein a curved structure protruding away from the second side surface along the first direction is formed in a middle portion of the jet plate, an annular structure extending outward is formed at an edge of the curved structure, the annular structure is connected to an edge of the second side surface, and the energy conversion cavity is defined by the curved structure and the second side surface; and/or
the piezoelectric assembly further comprises a support frame, wherein an edge of the second side surface is connected to the jet plate through the support frame, and the energy conversion cavity is defined by the second side surface, the support frame, and the jet plate.

9. The piezoelectric heat dissipation device of claim 7, further comprising a housing, wherein a second opening is provided on one side of the housing in the first direction, the piezoelectric assembly is arranged in the housing, the air exit plate is arranged to cover the second opening, and the housing is further provided with an air inlet in communication with the intake passage.

10. The piezoelectric heat dissipation device of claim 9, further comprising an elastic assembly, wherein the piezoelectric assembly is connected to the housing through the elastic assembly; and the elastic assembly comprises an elastic cantilever, a fixed end of the elastic cantilever is connected to a peripheral wall of the housing which extends in the first direction, and a free end of the elastic cantilever is connected to a side wall of the piezoelectric assembly which extends in the first direction.

11. The piezoelectric heat dissipation device of claim 10, wherein the elastic assembly comprises at least four elastic cantilevers, the at least four elastic cantilevers are arranged at intervals along a circumferential direction of the energy conversion cavity, and a free end of each of the at least four elastic cantilevers is connected to an outer peripheral wall of the energy conversion cavity.

12. The piezoelectric heat dissipation device of claim 9, wherein the air inlet is provided on a side of the housing facing away from the second opening in the first direction, or
the air inlet is provided on a peripheral wall of the housing which extends in the first direction; and
the piezoelectric heat dissipation device further comprises a baffle plate, wherein the baffle plate is connected to a side of the air exit plate facing away from the jet plate in the first direction, part of the baffle plate is spaced apart from the air exit plate to form an outlet passage, an air outlet perpendicular to the first direction is further provided on the baffle plate, and the air outlet is in communication with the air exit holes through the outlet passage.

13. The piezoelectric heat dissipation device of claim 7, wherein the piezoelectric heat dissipation device comprises a piezoelectric element, a diaphragm, a support frame, a jet plate, and an air exit plate, wherein
the support frame is provided with an energy conversion cavity which is open on two sides thereof in the first direction; and the diaphragm and the jet plate are respectively arranged to cover the two sides of the energy conversion cavity in the first direction and are connected to the support frame, the jet plate is provided with jet holes, the piezoelectric element comprises a first piezoelectric element and/or a second piezoelectric element, the first piezoelectric element is arranged on a side of the diaphragm facing away from the energy conversion cavity in the first direction, the second piezoelectric element is attached to a side of the jet plate facing away from the energy conversion cavity in the first direction, the piezoelectric element is provided with a central hole, the air exit plate is arranged spaced apart from the side of the jet plate facing away from the energy conversion cavity in the first direction, and the air exit plate is provided with air exit holes in communication with the jet holes.

14. The piezoelectric heat dissipation device of claim 13, wherein a projection of the piezoelectric element in the first direction is circular, and the central hole is a circular hole; and/or
the piezoelectric element is attached to the side of the jet plate facing away from the energy conversion cavity in the first direction, and a projection of each of the jet holes in the first direction falls within the central hole.

15. The piezoelectric heat dissipation device of claim 13, wherein a spacing dimension between the diaphragm and the jet plate in the first direction is defined as H₁ wherein 0.02 mm≤H₁0≤0.5 mm; and/or
a spacing dimension between the jet plate and the air exit plate in the first direction is defined as H₂ wherein 0.1 mm≤H₂≤2 mm.

16. The piezoelectric heat dissipation device of claim 13, wherein each of the jet holes is a circular hole, and a diameter of each of the jet holes ranges from 0.005 mm to 0.5 mm; and/or
diameters of the air exit holes are larger than diameters of the jet holes, and in the first direction, any one of the air exit holes is arranged corresponding to at least one of the jet holes.

17. The piezoelectric heat dissipation device of claim 13, wherein an area of a projection of the jet plate in the first direction is defined as S₁ a total area of projections of the jet holes in the first direction is defined as S₂and 0.1%≤S₂/S₁≤10%; and/or
wherein an area of a projection of the air exit plate in the first direction is defined as S₃ a total area of projections of the air exit holes in the first direction is defined as S₄ and 1%≤S₄/S₃≤20%.

18. The piezoelectric heat dissipation device of claim 13, further comprising a first connection assembly, wherein
the air exit plate is connected to an edge of the jet plate through the first connection assembly, or the air exit plate is connected to an edge of the diaphragm through the first connection assembly; and
the first connection assembly is provided with an intake passage in communication with the jet holes.

19. The piezoelectric heat dissipation device of claim 18, further comprising a housing, wherein the housing is provided with a window on one side thereof in the first direction, the air exit plate is arranged to cover the window, the piezoelectric element, the diaphragm, the support frame, and the jet plate are arranged in the housing, and the housing is provided with an air inlet in communication with the intake passage.

20. The piezoelectric heat dissipation device of claim 19, wherein the air inlet is provided on a side of the housing facing away from the window in the first direction.
